(19) United States
(12) Patent Application Publication
(10) Pub. No.: US 2025/0266685 A1
(43) Pub. Date: Aug. 21, 2025

(54) MICROGRID SYSTEMS AND RELATED METHODS

(71) Applicants: Michael N. Abraham, Pagosa Springs, CO (US); Battelle Energy Alliance, LLC, Idaho Falls, ID (US)

(72) Inventors: Robert J. Turk, Idaho Falls, ID (US); Kurt S. Myers, Idaho Falls, ID (US); Porter J. Hill, Shelley, ID (US); Jeremiah Gilbert, Idaho Falls, ID (US); Michael N. Abraham, Pagosa Springs, CO (US)

(21) Appl. No.: 18/444,449

(22) Filed: Feb. 16, 2024

(51) Int. Cl. H02J 3/32; H02J 3/18; H02J 13/00; H05K 7/20

(52) U.S. Cl. CPC H02J 3/32; H02J 3/18; H02J 13/00001; H02J 13/00002; H02J 2203/10; H05K 7/20145

(57) ABSTRACT

A microgrid system may include a portable enclosure containing at least one energy storage device, at least one inverter, a switchgear, at least one processor, and at least one non-transitory computer readable storage medium storing instructions thereon that cause the microgrid system to measure, a frequency or a voltage to generate first frequency data or first voltage data, provide, via a graphical user interface of the microgrid system, the first frequency data and the first voltage data to an operator of the microgrid system, receive one or more of a center point voltage parameter, a center point frequency parameter, and a power discharge bias parameter, and while maintaining active operation of the at least one inverter, update operating parameters of the at least one inverter responsive to the received one or more of the center point voltage parameter, the center point frequency parameter, and the power discharge bias parameter.

### STATEMENT REGARDING FEDERALLY SPONSORED RESEARCH OR DEVELOPMENT

This invention was made with government support under Contract No. DE-AC07-05-ID14517 awarded by the United States Department of Energy. The government has certain rights in the invention.

### TECHNICAL FIELD

Embodiments of the disclosure relate generally to systems and methods for activity detection using machine-learning.

### BACKGROUND

The world's power demand is increasing, with fossil fuels remaining the leading energy provider, and renewable energy resource system at a close second. Solar Photovoltaic (PV) systems are growing rapidly in the United States, with additional capacity projections to exceed 1,600 GW to help decarbonize the U.S. electric grid by 2050. In short-term projections, solar photovoltaic (PV) production will surpass coal, hydropower, and natural gas by 2026 to become the global cumulative power capacity leader. The distribution landscape is rapidly changing from standard load-providing distribution feeders to capable bidirectional power flow distribution feeders resulting from the growing high-penetration (HP) energy asset installations that include feeders containing 50% or more inverter re-sources at the local consumer level. These HP inverter-based grid voltages are impacted most by the abundant supply of solar PV technology compared to other natural resources, including wind generation. The power fluctuations are instantaneous due to outside weather factors that create system contingencies, including reverse power flow and voltage sags requiring advanced protection schemes driving the economic liability onto the interconnected utility. Volt-VAR directional inverter controls may not supply the necessary volt-ampere reactive (VAR) support to counter these voltage fluctuations. Currently, low-voltage ride-through capabilities are typically not utility-mandated for small generating facilities. Utilities are not required to support low-voltage ride-through scenarios but enact strict interconnection agreements on how the inverter-based power resources will be utilized. Limiting HP inverter-based power resources on distribution feeders without proper monitoring or controls may be a slippery slope.

### BRIEF SUMMARY

Some embodiments of the disclosure include a microgrid system. The microgrid system may include a portable enclosure. The portable enclosure may contain at least one energy storage device, at least one inverter operably connected to the at least one energy storage device, a switchgear operably connected to the at least one inverter, at least one processor, and at least one non-transitory computer readable storage medium storing instructions thereon that, when executed by the at least one processor, cause the microgrid system to measure, at a point-of-interconnect of the microgrid system, a frequency or a voltage to generate first frequency data and first voltage data, provide, via a graphical user interface (GUI) of the microgrid system, the first frequency data or the first voltage data to an operator of the microgrid system, receive one or more of a center point voltage parameter, a center point frequency parameter, and a power discharge bias parameter, and while maintaining active operation of the at least one inverter, update one or more operating parameters of the at least one inverter responsive to the received one or more of the center point voltage parameter, the center point frequency parameter, and the power discharge bias parameter.

Further embodiments of the disclosure include a method. The method may include measuring, at a point-of-interconnect of a microgrid system, a frequency and a voltage to generate first frequency data and first voltage data, providing, via a graphical user interface (GUI) of the microgrid system, the first frequency data or the first voltage data to an operator of the microgrid system, receiving one or more of a center point voltage parameter, a center point frequency parameter, and a power discharge bias parameter, and while maintaining active operation of the at least one inverter, updating one or more operating parameters of the at least one inverter responsive to the received one or more of the center point voltage parameter, the center point frequency parameter, and the power discharge bias parameter.

Further embodiments of the disclosure may include a non-transitory computer readable storage medium storing instructions thereon that, when executed by the at least one processor, cause the microgrid system to measure, at a point-of-interconnect of a microgrid system, a frequency and a voltage to generate first frequency data or first voltage data, provide, via a graphical user interface (GUI) of the microgrid system, the first frequency data or the first voltage data to an operator of the microgrid system, receive one or more of a center point voltage parameter, a center point frequency parameter, and a power discharge bias parameter, and while maintaining active operation of the at least one inverter, update one or more operating parameters of the at least one inverter responsive to the received one or more of the center point voltage parameter, the center point frequency parameter, and the power discharge bias parameter.

### BRIEF DESCRIPTION OF THE SEVERAL VIEWS OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings, in which:

FIG. 1 illustrates a schematic diagram of a portable microgrid system configured to implement inverter-based microgrid control architectures to support a power grid according to one or more embodiments of the disclosure;

FIG. 2 is a flowchart illustration of a process of the microgrid system according to one or more embodiments of the disclosure;

FIG. 3A is an example graphical user interface (GUI) for a Frequency-Watt and Volt-Watt control function of the microgrid system that may define one or more charge/discharge profiles for the one or more energy storage devices, according to one or more embodiments of the disclosure;

FIG. 3B shows and example GUI for a Volt-VAR control function of the microgrid system for modifying one or more parameters of a Volt-VAR curve, according to one or more embodiments of the disclosure;

FIG. 4A illustrates a Frequency-Watt control curve centered at 60 Hz according to one or more embodiments of the disclosure;

FIG. 4B shows the Frequency-Watt curve which is representative of the Frequency-Watt curve shown in FIG. 4A, but modified with a 20% increase (discharging) in a frequency-watt bias parameter according to one or more embodiments of the disclosure;

FIG. 4C shows the Frequency-Watt curve which is representative of the Frequency-Watt curve shown in FIG. 4A, but modified with a 20% decrease (charging) a Frequency-Watt bias parameter according to one or more embodiments of the disclosure;

FIG. 4D shows the Frequency-Watt curve which is representative of the Frequency-Watt curve shown in FIG. 4A, but modified to have a frequency deadband midpoint of 59.7 Hz according to one or more embodiments of the disclosure;

FIG. 4E shows the Frequency-Watt curve which is representative of the Frequency-Watt curve shown in FIG. 4A, but modified to have a frequency deadband midpoint of 60.3 Hz according to one or more embodiments of the disclosure;

FIG. 4F shows the Frequency-Watt curve which is representative of the Frequency-Watt curve shown in FIG. 4A, but modified to have a maximum power end point changed from 61.5 Hz to 61.0 Hz according to one or more embodiments of the disclosure;

FIG. 5A shows an example response of the microgrid system to a voltage sag experience by the microgrid system according to one or more embodiments of the disclosure;

FIG. 5B shows an example response of the microgrid system to a voltage swell experienced by the microgrid system according to one or more embodiments of the disclosure;

FIG. 5C shows an example response of the microgrid system to a voltage sag followed by a voltage swell including a change in voltage bias response according to one or more embodiments of the disclosure;

FIG. 6 shows a schematic representation of a top view of an example layout of a portable microgrid system according to one or more embodiments of the disclosure;

FIG. 7 is a block diagram of circuitry that, in some examples, may be used to implement various functions, operations, acts, processes, and/or methods disclosed herein.

### DETAILED DESCRIPTION

A microgrid is an integrated energy system that may manage distributed generations, energy storage systems, and responsive loads in both normal as well as abnormal operating conditions. During some operating conditions for either grid connected or islanded (e.g., not connected to an outside energy grid), energy efficiency and economic operations may be considerations. However, during abnormal operating conditions and transitions, technical aspects such as stability, resiliency, and energy security become concerns. Due to increased needs for energy security and resiliency of power supply, power quality and reliability have become prominent concerns relating to operating an energy system.

A microgrid may be used to offer more control over power/energy supply, energy security and resiliency, reliability, availability, resiliency improvement, and more distributed fuel sources. As some examples, microgrid use cases may include fuel use/shipment reductions, energy demand management, voltage support, power quality improvements/flexibility, transmission, and distribution congestion management, upgrade mitigation, outage management/backup power, etc. A microgrid may also offer energy management and use control, improved power system knowledge/metering and control, enable the ability to optimize investments, asset sizing, and improving system architectures, usability (e.g., Uninterruptible Power Supply (UPS)) with lead acid batteries and diesel gensets versus more flexible energy storage and genset options, enable optimal loading on generator set (genset), non-spinning reserve, turn off gensets at times and still pick up load changes, allow time to spin up additional gensets, and improve meeting green energy goals and facilitate knowledge of energy supply.

Microgrid services for electric power systems have, in the past, been defined as ancillary services, such as power regulation and frequency response, spinning and non-spinning reserves, etc., to support the reliable and stable operations of electric power systems. These may include reliability services that may be deemed necessary for managing frequency, voltage, net area demand and dispatchability. Other services may include scheduling, system control, and dispatching; reactive supply and voltage control from generation resources; regulation and frequency response; energy imbalance; operating (spinning) reserve; and operating (supplemental) reserve services.

Many considerations may be at issue when using a microgrid. For example, a microgrid may be relied upon to analyze and determine desired power and energy penetration levels of variable generation (i.e., solar photovoltaic (PV)), load profiles, generation profiles, fueled generator load levels, amounts of storage and load control to enable designs for stable and optimal control, fuel use/durations and mission/energy security. Storage considerations may include fuel tanks, batteries, natural gas systems (pipelines, bulk storage), hydro, LPG/CNG/LNG, hydrogen, thermal, etc. Moreover, use of a microgrid may vary depending on whether the goal is to design for times of fueled generation off, certain number of spinning generators always on, set amounts of spinning reserve, or other considerations. Further considerations may include what control functions are available in inverters, fueled gensets, secondary control systems, etc., that allow for optimal system integration/control (i.e., droop, isochronous, advanced droop coordination, Phasor Measurement Unit (PMU)-based control, etc.) or what modifications need to be developed or added to the primary and secondary control systems to achieve desired results for all modes/use-cases.

Additionally, consideration of integration of other devices to improve stability or operability may be considered. For example, secondary, tertiary control loops/algorithms, battery storage systems with advanced inverter functions/controls, flywheels, Static VAR Compensator (SVC), Dynamic VAR Compensator (DVAR), and/or switched components for Volt-VAR control, system protection and electrical power improvements may be integrated with the microgrid system to further improve stability or operability of the microgrid system. Considerations may be different when generation is distributed closer to loads and connected within distribution panels. Still further considerations may include whether fueled gensets are all a same size or varying sizes to match up with net load profiles more effectively and to make sure storage and genset combinations may pick up and manage swings or steps in variable generation and loads as sizing of these may be beneficial for both power and energy capacities and for protection design and inrush considerations.

Inverter-based resources face growing concerns due to their inability to support grid stability without onsite Battery Energy Storage System (BESS) when combating rapid transients at the distribution level with existing control schemes. Simple unplanned cloud coverage weather events on solar PV installations without proper mitigation plans may result in widespread blackouts due to a voltage sag reaching the system's saturation limits. This may be due to the inability of HP inverter sources to provide the necessary VAR support typically provided with spinning generation assets due to their capability to absorb and supply reactive power. The decreasing share of spinning generation assets, which are being replaced by solar PV and wind resources lacking a BESS that currently does not provide VAR support may be a concern as the energy infrastructure landscape shifts to support renewable energy resources. There are various technologies, including flexible AC transmission systems (FACTS) devices, to maintain voltage stability. Still, they may not be economically viable at the distribution level to implement at local points of interconnect compared to a control framework implemented using standard PV installation equipment. Utility companies have started to limit the consumer integration of inverter-based power sources on current HP distribution feeders due to the power variabilities. Limiting consumer PV installations at a local distribution level due to the lack of controls and infrastructure may create a roadblock to future goals of creating a net-zero power grid.

Moreover, some Volt-VAR controls work at a low penetration level using maximum power point tracking (MPPT) control integrating active power calculations relaying the data to its inverter control system, which may use pulse width modulation to reflect VAR support needs to the inverter. This conventional control method is successful under low penetration distribution systems that receive most of its var support from the spinning generation assets. When conventional Volt-VAR or Frequency-Watt controls are activated, it is usually a standard to stabilize real or reactive power. Some Volt-VAR controls also have economic limitations due to the current power agreements between utilities and power producers. Utility companies may only pay for real power metered production, while reactive power remains uncompensated. However, inverters must provide at least 5% of VAR support of its rated apparent power.

Furthermore, for some BESS inverters, there may be only two points that may be controlled on the fly, such as droop curve deadband center point frequency adjust, and the droop slope (but in some inverters the slope may not be adjusted while running) for the frequency curve, and Voltage and its droop slope for the voltage part of the control (e.g., when the inverter is in full droop, grid-forming voltage-source mode). The “deadband” refers to a range of values defined by a curve (e.g., a droop curve) where no control action occurs. Stated another way, the deadband defines a nominal operating range for a system utilizing the curve including the deadband. When in grid following (i.e., current source), some inverters have some forms of limited Frequency-Watt and Volt-VAR modes and may only be operated in one of those modes at a time. Often those modes are not fully active or are very limited, and, for example, the user may not be able to move the center point setting away from 60 Hertz for Frequency-Watt modes. Therefore, the operator may not use that Frequency-Watt mode for a full droop control with more adjustability for more deliberate flows of power in one direction or the other. Furthermore, in many inverters, the programmed Frequency-Watt or Volt-VAR curve points may not be adjusted while the inverter is running. The inverter has to be stopped, points changed, and then re-started to adjust the associated responses. Because of this, many system controllers may use much slower P and/or Q commands from an overarching controller (with more sophisticated algorithms, etc.) to perform frequency and voltage regulation services on power grids, which may not be fast enough to provide primary frequency and voltage control, especially in smaller grids where there may be smaller amounts of conventional, spinning generators.

Accordingly, to provide a microgrid capable of being used in more versatile ways and in diverse environments, one or more embodiments of the disclosure includes a microgrid system. The microgrid system may include an inverter, switchgear, and one or more energy storage devices within a portable container that may be connected to a power grid to offer power support to the power grid. Moreover, one or more microgrid control methods may be used to provide necessary Volt-VAR or Frequency-Watt support to a power grid to maintain grid stability. For example, the methods disclosed herein may provide bidirectional VAR support by leveraging metering data at the point of common coupling to enable real-time decisions based on voltage measurements. This control approach may allow the standard directional power flow approach that the inverters lacking onsite batteries are accustomed to. An advanced Volt-VAR control scheme using inverter-based power electronics on HP grids may allow voltage ride-through capabilities abiding by current National Electric Code (NEC) standards, respond to voltage sags and swells, and combat fast transients. This control scheme may reduce response times to provide grid stability by responding to voltage sags, voltage swells, and other transient scenarios at the point of common coupling that will allow for HP levels of inverter-based assets.

The microgrid system described herein may be faster to deploy since additional external components (i.e., switchgear and additional breaker panels and generator interconnection systems) are minimized, may utilize a safer lithium battery chemistry (lithium iron phosphate LFP), may be rated for regular transport and movement, may have minimized the need for long, side-door panels on the long sides of the shipping container for battery cubicles access, may have a DC expansion port and cable tray system to add more battery capacity on the DC electrical side using additional container(s) but may not need additional switchgear or on-ground cabling or conduits, and may not be not just a utility-tie and distribution grid support BESS system like some conventional microgrid systems.

Additionally, the microgrid systems discussed herein, with a large amount of energy storage as a main stabilizing, power ramping and energy shifting power component, may be applied in many microgrid, distributed energy, military, and utility/industry/commercial support applications. For example, the microgrid system discussed herein may improve capabilities for and increasing levels of renewable energy and variable power generation systems integration, along with adding more flexibility to generation resources that may not be able to (or not desired to) ramp and vary their output as needed to follow loads (less-flexible resources such as base-load generation). Some of the use-cases for this system (including scaled versions with multiple units/systems paralleled together) include as power supplies for disaster relief, community microgrids, utility distribution systems support, feeder and power congestion management, transmission and distribution line upgrade deferments, to enable larger amounts of variable renewable energy generation to be integrated into utility power systems, etc.

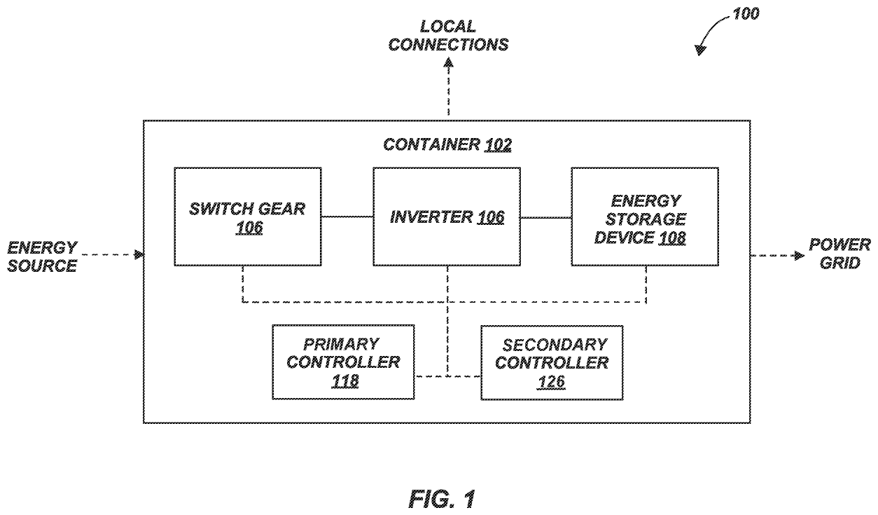

FIG. 1 illustrates a schematic diagram of a portable microgrid system 100 configured to implement inverter-based microgrid control architectures to support a power grid according to one or more embodiments of the disclosure. The microgrid system 100 includes a portable container 102. The container 102 includes a switchgear 104, an inverter 106, and at least one energy storage device 108. The container 102 also includes a primary controller 118 and a secondary controller 126, which may each be operably connected to the switchgear 104, inverter 106, and the at least one energy storage device 108. The switchgear may be operably connected to the inverter 106 and the inverter 106 may be operably connected to the energy storage device 108.

The switchgear 104 may be configured to manage electrical distribution within the microgrid system 100. For example, the switchgear 104 may include devices such as circuit breakers or relays to detect and respond to electrical faults such as short circuits, overloads, or other potential electrical problems. The switchgear 104 may control the opening or closing of switches and circuit breakers of the microgrid system 100 to allow operators to manage the distribution of power within the microgrid system 100. In some embodiments, the microgrid system 100 may include a plurality of energy storage devices 108 where the switchgear may be operably connected to the plurality of energy storage device 108 and may be operable to monitor and control the flow of energy to and from the plurality of energy storage devices 108.

The inverter 106 may allow the microgrid system 100 to connect to an energy source to allow energy to flow from the energy source to the microgrid system 100. For example, the inverter 106 may be configured to convert a direct current (DC) from an energy source (e.g., solar, wind, nuclear, etc.) into alternating current (AC) so that the energy may be used by the microgrid system 100. Furthermore, the inverter 106 may align power (e.g., electrical power) received from an energy source and align it with a standard grid voltage and/or frequency, such as a voltage and/or frequency standard of a power grid to which the microgrid system 100 is attached. For example, the inverter 106 may receive DC from a renewable energy source such as a PV (solar) source and may convert the DC into AC and control the magnitude and phase of the AC output to match the power requirements of the power grid. Furthermore, the inverter 106 may connect to a plurality of energy storage devices 108 included in the microgrid system 100 and control the charging or discharging of the plurality of energy storage device 108 according to one or more charge or discharge profiles. In some embodiments, the microgrid system 100 may operate in connected or islanded (separate from a main power grid) modes. When operating in the islanded mode, the inverter 106 may enable the generation and distribution of power within the microgrid system 100 and may also control providing power to local loads connected to the microgrid system 100.

In some embodiments, the microgrid system 100 may include a user device (not shown) configured to allow a user to interface with the switchgear 104, inverter 106, and/or the energy storage device 108 (e.g., via controller 118). The user device may include a display configured to show a graphical user interface (GUI) to facilitate an interface between a user and the microgrid system 100. The user device may be a mobile device (e.g., a cell phone, a smartphone, a PDA, a tablet, a laptop, a watch, a wearable device, etc.). In some embodiments, however, the user device may be a non-mobile device (e.g., a desktop or server). In some embodiments the user device may be integrated within the microgrid system 100 within the container 102. In other embodiments, the user device may be a remote device configured to interface with the microgrid system 100 over a wired or wireless connection to the microgrid system 100.

In some embodiments, the controller 118 may control one or more operations of the inverter 106. For example, the controller may execute instructions responsive to one or more operating parameters provided by an operator to change one or more operations of the inverter based on a detected load at a point of interconnect with the inverter 106. For example, a point of interconnect may be where an energy source (e.g., a renewable energy source) connects to the inverter 106 to allow the inverter 106 to change one or more properties of the energy supplied by the energy source. In some embodiments, the inverter 106 may include a plurality of inverters of varying types. For example, the inverter 106 may include solar inverters, battery inverters, wind inverters, hybrid inverters, grid-forming inverters, etc., and may be configured to perform operations in both grid-tied and islanded operations.

The secondary controller 126 may be configured to interface with the primary controller 118. For example, the secondary controller 126 may be in communication with the primary controller 118 such that the secondary controller may, via the primary controller 118, change one or more settings of the microgrid system 100. In some embodiments, the secondary controller may allow for an operator to change one or more settings of the secondary controller (and thereby settings of the primary controller 118 or the microgrid system 100) via a Human Machine Interface (HMI) such as a graphical user interface (GUI). Furthermore, in some embodiments, the secondary controller 126 may allow for one or more other controllers (e.g., controllers at a higher logic level than the secondary controller 126) to interact with and change settings of the microgrid system 100. By incorporating the secondary controller 126, a layered control approach may be taken to allow for greater control of the microgrid system and allow an operator to use a HMI to change one or more settings of the microgrid system 100 without the need to turn off or restart the microgrid system 100.

The energy storage device 108 included in the microgrid system 100 may include Lithium Iron Phosphate batteries which may provide safety and portability, although in one or more embodiments, other battery chemistries and types may be used if specifications and use-case requirements are met. Furthermore, systems described herein may be implemented to include design, integration, custom containerization, trailer mounting/provision and a portable inverter/battery system, space conditioned, containerized combination system, with 250 kW total of grid-tie/grid-forming/islanding inverters for 3-phase, power supply as detailed above, with 250 kW/320 kWh of Li iron phosphate battery storage and controls, electrical connection provisions for up to 250 kW of AC coupled solar inverters or other clean energy generation resources that route through inverters, full microgrid system controls, systems integration and containerization with all balance of system wiring, wireways/enclosures and other electrical components to enable external and manageable connection of an energy source such as a solar PV systems (or other inverter-based generation), diesel generator and utility grid ties and connections. Portable and deployable energy generation blocks may be connected into and managed by the microgrid system 100 as needed/available. These may include solar, wind, micro-nuclear, liquid or gas fueled resources, hydrogen-based, etc.

Further aspects of the disclosed microgrid system 100 and methods include a switchable frequency and voltage capability, to enable use of this system in both US-type power grids at 480 VAC three-phase, 60 Hz, and UK-type power grids at 415 VAC three-phase, 50 Hz, and that the utility grid and synchronous generator connections, coordinating and synchronizing switchgear is customized but UL-listed, and contained within the 20-foot length shipping container footprint and housing, and rated for up to a 400 amp electrical utility service. In some microgrid systems, the switchgear footprint may be larger and unable to be fitted within the 20-foot container along with all the other batteries and grid-forming inverter equipment, and frequently have external switchgear systems.

In some embodiments, the microgrid system 100 may include the ability to integrate with and control other energy generation resources such as microreactor nuclear power systems with Stirling generators for power conversion, other Stirling generator power generation systems with other fuel/heat inputs, fuel cell or linear generator systems that run on 100% hydrogen or ammonia, or any other distributed generation resource that gets converted through AC-coupled inverter/power-conversion systems to tie into a microgrid. This microgrid system 100 may be able to perform in multiple grid-forming and grid-following control modes, and stacked mode uses using multiple, advanced secondary/tertiary control systems communicating to the primary controls of the grid-forming inverters, switching modes as appropriate and adjusting voltage and frequency droop curve settings (or other mode curve/parameter settings) on the fly (e.g., while operating) (e.g., adjusting voltage and frequency droop curve settings without the need to power down the inverter). Many conventional microgrid inverters need to be shut off before setting changes are made, and then turned back on, but the microgrid system 100 may be able to make changes while on, grid-tied, islanded and generator-tied, and operating by utilizing an HMI and the secondary controller 126 to offer layered control support of the microgrid system 100.

The microgrid system 100 may also include a UPS powered, thermally-triggered louver and venting system, to vent off-gassing for fire responder safety in the event of a fire inside of the container. It may also be trailer-mounted on a heavy gooseneck trailer for movability and transport, and since the main components are all mounted in its shipping container, the microgrid unit may be decoupled and put on a different trailer such as a full semi-truck type trailer for shipping containers, or the container may be placed onto a concrete pad or other type of ground pad area or system, for temporary or longer-term use-cases.

In some embodiments, the microgrid system 100 may include a plurality of energy storage devices 108 such that the microgrid system 100 may power a 125 kW-250 kW sized commercial/end-user building/facility, for multiple hours, with switchable power ratings between 415/230 VAC, 50 Hz, three-phase to 480/277 VAC, 60 Hz three-phase, and including controls for specified functions during both grid-tied and islanded operations may be provided that may be suitable for diverse environments (e.g., the Middle East and or utility/commercial/industrial environments and distributed microgrid use-cases).

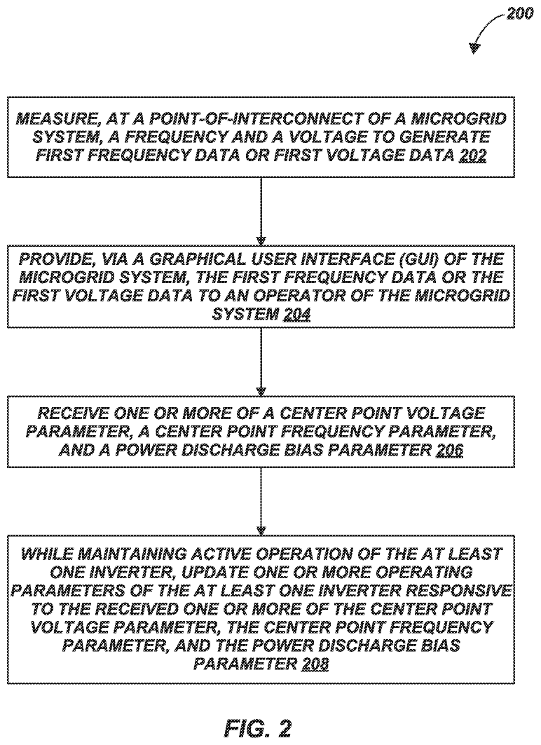

FIG. 2 shows an example process 200 of the microgrid system 100 via a schematic flow diagram. For instance, FIG. 2 shows one or more embodiments of a simplified sequence-flow that the microgrid system 100 may utilize to detect power variances at a point of interconnect of the microgrid system 100 and implement changes to one or more operating parameters of the microgrid system 100.

In some embodiments, the process 200 may include measuring, at a point-of-interconnect of a microgrid system, one or more of a frequency and a voltage to generate first frequency data and first voltage data, as shown in act 202 of the process 200. For instance, an energy source may be connected to the microgrid system 100 via the inverter 106 where the location of the connection between the energy source and the inverter 106 may be referred to as a “point of connection” between the energy source and the inverter 106. The microgrid system 100 may utilize one or more sensors included in the microgrid system 100 to sample a voltage and/or frequency of an electrical current received at a point of interconnect between an energy source and the inverter 106. In some embodiments, the one or more sensors of the microgrid system 100 may sample the electrical current at the point of interconnect several times a second. For example, the one or more sensors may sample the electrical current at the point of interconnect between about one time and about eight times per second.

The microgrid system 100 may provide, via a graphical user interface (GUI) (i.e., a HMI) of the microgrid system 100, the first frequency data or the first voltage data to an operator of the microgrid system, as shown in act 204 of the process 200. For example, the first frequency data or the first voltage data may be provided to a GUI displayed via the display of the user device included in the microgrid system 100. The first frequency data and the first voltage data may inform the operator as to the current frequency and voltage measured at the point of interconnect between the energy source and the inverter 106 which may allow an operator to be informed as to which parameter changes need to be made to adjust one or more operations of the microgrid system 100 to support the electrical current supplied by the energy source. The microgrid system 100 may receive one or more of a center point voltage parameter, a center point frequency parameter, and a power discharge bias parameter, as shown in act 206 of process 200. For instance, an operator may utilize the user device of the microgrid system 100 to input at least one or more of a center point voltage parameter, a center point frequency parameter, and a power charge/discharge bias parameters. While maintaining active operation of the at least one inverter, the microgrid system 100 may update one or more operating parameters of the at least one inverter responsive to the received one or more of the center point voltage parameter, the center point frequency parameter, and the power discharge bias parameter, as shown in act 208 of process 200. For example, microgrid system 100 may adjust the system voltage based on user-defined characteristics including the nominal voltage center setpoint, dead band, saturation limits, and a bias by injecting (i.e., providing) or absorbing VAR. Equations (1) and (2) below provide context to represent the charge and discharge determined automatically calculated based upon the user (e.g., an operator) input.

$${P}_{\% {max}_{cha}} = {m}_{chg} ( {V}_{midpt} ) + {P}_{{bias}_{cha}} \qquad ( 1 )$$

$${P}_{\% {max}_{discha}} = {m}_{dischg} ( {V}_{midpt} ) + {P}_{{bias}_{discha}} \qquad ( 2 )$$

The equations may determine the maximum power percentage the microgrid testbed inverters may now support based on the midpoint characteristics. Equation (1) represents a system charging state taking into consideration the charge profile (m_{chg}), center point voltage setting (V_{midpt}), and the power charge bias (P_{bias}_{_{chg}}). Similarly, Equation (2) represents a system discharging state as a function of discharge profile (m_{dischg}), center point voltage setting (V_{midpt}), and the power discharge bias (P_{bias}_{_{dischg}}). Internal to the equations, the user defined setpoints are applied. The charge and discharge max power percentage will linearly distribute reactive power support using the Volt-VAR framework. The (P_{bias}_{_{chg}}) is an input allowing for higher BESS functionality while responding to voltage transients. The (m_{chg}) and (m_{dischg}) are directly correlated to the (P_{bias}_{_{chg}}) setpoint that determines the amount of reactive power support that may now be provided to maintain the grid's voltage stability based on the (V_{midpt}). The user (i.e., the operator) may define the center set point based on the system's nominal operating voltage. Standard deviations from the microgrid testbed's nominal voltage may be tolerated at the distributed power level and operator defined by implementing an NEC-compliant dead band voltage range, allowing for, for example, a minimum of 5% flexibility before the possible point of interconnect disturbances or VAR support scenarios may occur. When the microgrid system's 100 voltage leaves the dead band range, the algorithm may utilize the local BESS to linearly inject or absorb reactive power as the voltage deviates further from the nominal voltage center setpoint until the system is back within its dead band or the inverter has reached its defined saturation limits. Within the algorithm, the operator may determine the saturation limits to quantify the reactive power the system will provide to support the voltage. If the saturation limits do not adequately coordinate with the microgrid's needs, under and over-voltage limits may cause the microgrid system 100 to disconnect from the grid. The ability to change the bias provides layered support by adjusting the overall charge and discharge of the energy storage device 108 of the microgrid system 100 while reacting to voltage transients requiring VAR support.

Stated another way, if frequency or voltage detected at a point of interconnect between an energy source and the inverter 106 of the microgrid system 100 go above or below desired nominal levels and outside of deadband settings, the microgrid system 100 may provide or absorb power from the combination of the energy storage device 108 and the inverter 106 to help bring the microgrid system 100 frequency or voltage back closer to the nominal level. The farther away the microgrid system 100 goes from nominal, the more power is injected or absorbed. Using the bias and/or deadband adjustments, a more continual, higher level of power may be injected or absorbed to help the system even further. In other words, the microgrid system 100 may absorb or provide reactive power responsive to updating the bias and/or the deadband parameters. Moreover, if one wants the power response to be more or less aggressive, the slope of the line on either side of the deadband may be adjusted with the endpoints of the function curve.

In some embodiments, the microgrid system 100 may detect when the voltage or frequency detected at the point of interconnect between the energy source and the inverter 106 deviates from a pre-defined voltage range or frequency range. For example, the microgrid system 100 may detect when a detected voltage or frequency has deviated from a deadband portion of a defined Frequency-Watt curve, Volt-Watt curve, or Volt-VAR curve. In some embodiments, the microgrid system 100 may generate one or more alerts responsive to detecting that a detected voltage or frequency has deviated from a predefined voltage range or frequency range, respectively. In some embodiments, the generated one or more alerts may be sent to an operator via a display of the user device of the microgrid system 100.

Referring to FIGS. 1-2 together, the microgrid system 100 may enhance traditional inverter Volt-VAR or Frequency-Watt control schemes by integrating a controllable power bias that allows additional BESS support to react with situational Volt-VAR stabilization while allowing for other system responses, including peak shaving, load shed, and different utility support needs without the need to power down components of the microgrid system 100 to make the changes. Allowing a bias to be incorporated into a multi-layered control approach may enable advanced transient response controls that change based on the connected loads and generation conditions, enabling longer time constants on charge and discharge profiles. For example, when it is midday and a bias is utilized for a peak shaving scenario that experiences cloud coverage on solar PV or a large load is applied or removed from the system, the microgrid system 100 controls may respond to the short-term transient and meet the peak shaving objective. Using this fast-response algorithm, the microgrid system 100 may function as a valuable grid asset, offering support at the interconnect point for inverter-based distributed generation resources. This setup may provide flexibility for integrating different generation resources while maintaining grid stability. The layered control approach may increase the overall penetration of the inverter-based power generation source while providing grid stability.

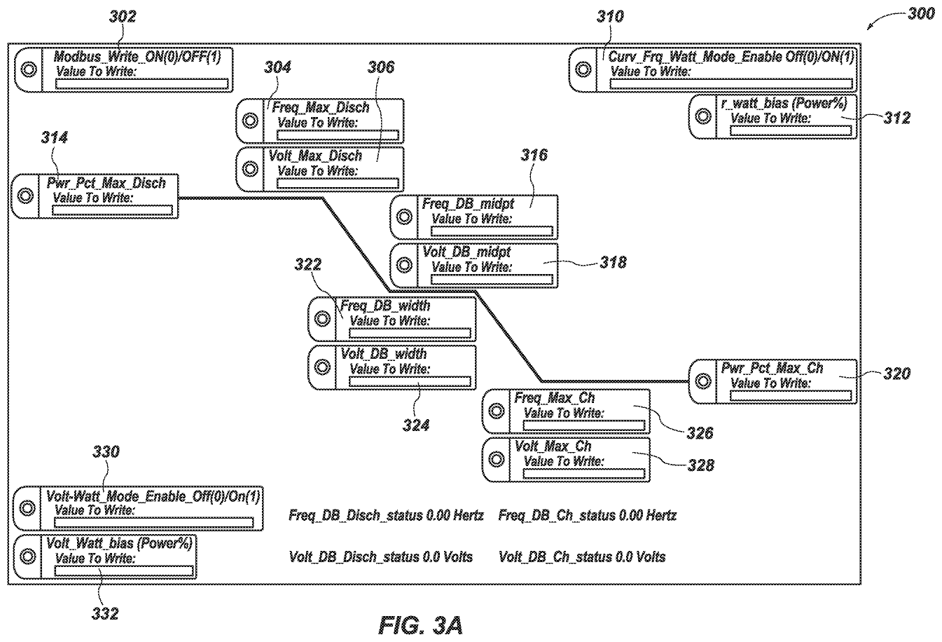

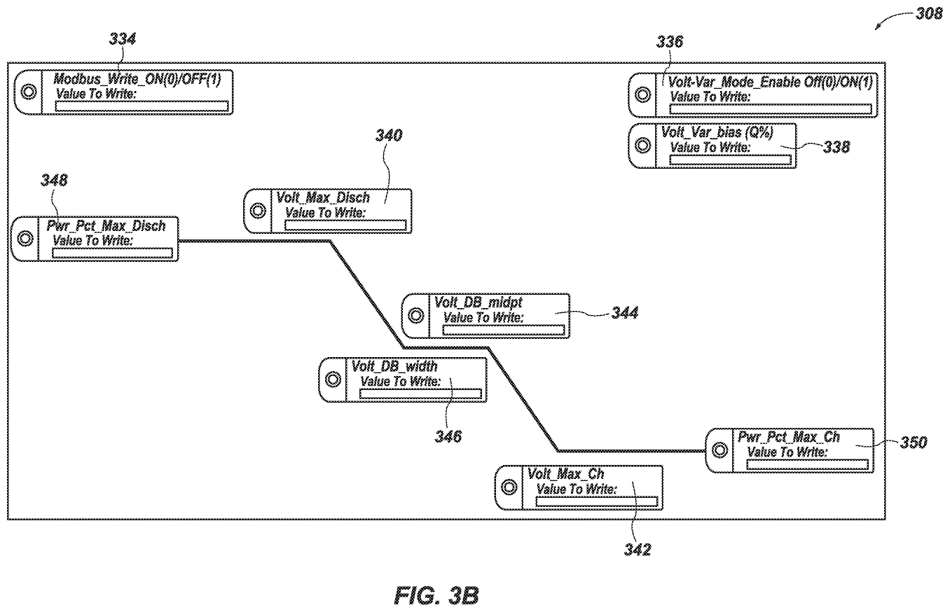

FIG. 3A is an example graphical user interface (GUI) 300 for a Frequency-Watt and Volt-Watt control function of the microgrid system 100 that may define one or more charge/discharge profiles for the one or more energy storage devices 108, according to one or more embodiments of the disclosure. The GUI 300 may include a number of selectable elements that may be selected by a user via an input/output (I/O) device and modified to change one or more operations of the microgrid system 100. The selectable elements include a Modbus Write toggle element 302, a Frequency-Watt mode enable toggle element 310, a Frequency-Watt bias element 312, a Volt-Watt mode enable toggle element 330, a Volt-Watt bias element 332, a power percentage maximum discharge element 314, a power percentage maximum charge element 320, a Frequency maximum Discharge element 304, a voltage maximum discharge element 306, a frequency deadband midpoint element 316, a voltage deadband midpoint element 318, a frequency deadband width element 322, a voltage deadband midpoint element 318, a voltage deadband width element 324, and a voltage maximum charge element 328.

The frequency deadband midpoint element 316 and the frequency deadband width element 322 may be used to define a nominal frequency deadband range. Likewise, the voltage deadband midpoint element 318 and the voltage deadband width element 324 may define a nominal deadband voltage range. Furthermore, the frequency maximum discharge element 304 and the frequency maximum charge element 326 may define a maximum frequency charge or discharge threshold. In some embodiments, the settings (e.g., the selectable elements) related to Frequency-Watt settings may not be accessible at the same time as the settings related to Volt-Watt settings. Accordingly, the Volt-Watt mode enables toggle element 330 and Frequency-Watt mode enable toggle element 310 may be used to switch which settings may be changeable at a given time.

FIG. 3B shows an example GUI 308 for a Volt-VAR control function of the microgrid system 100 for modifying one or more parameters of a Volt-VAR curve, according to one or more embodiments of the disclosure. The GUI 308 may include a number of selectable elements that may be selected by a user via an I/O device and may be modified to change one or more operations of the microgrid system 100. The selectable elements include a modbus write toggle element 334, a Volt-VAR mode enable toggle element 336, a Volt-VAR bias element 338, a power percentage maximum discharge element 348, a power percent maximum charge element 350, a voltage maximum discharge element 340, a voltage maximum charge elements 342, a voltage deadband midpoint 344, and a voltage deadband width 346. The voltage deadband midpoint 344 and the voltage deadband width 346 may be used to define a nominal deadband voltage range. In some embodiments, the Volt-VAR settings shown in by GUI 308 may be operated on at the same time as the Frequency-Watt settings shown in FIG. 3A.

Referring to both FIGS. 3A and 3B together, the active Volt-VAR control may have its deadband easily shifted below or above 60 Hz as needed to achieve the desired overall system voltage in the nearby distribution grid area, and/or we may adjust with the VAR-bias as well. And all of those setpoints may be modified while the system is running. This is also true for the Volt-Watt and Frequency-Watt modes. By utilizing Volt-VAR+Watt, the microgrid system 100 may perform voltage regulation at the same time as energy shifting or peak shaving with the Watt side of that control mode.

Stated another way, the way the above slope controls work are that the farther below the deadband the voltage or frequency goes, the more Watts or VARs may be injected into the distribution grid. And, the farther above Voltage or frequency go, the more Watts or VARs are absorbed. Furthermore, the microgrid system 100 may recalculate the slopes in every controller compute cycle, so that the control points may be adjusted on the fly while running the system and also allow more than one mode/function to be happening at the same time, thus offering a layered control approach not offered by conventional systems.

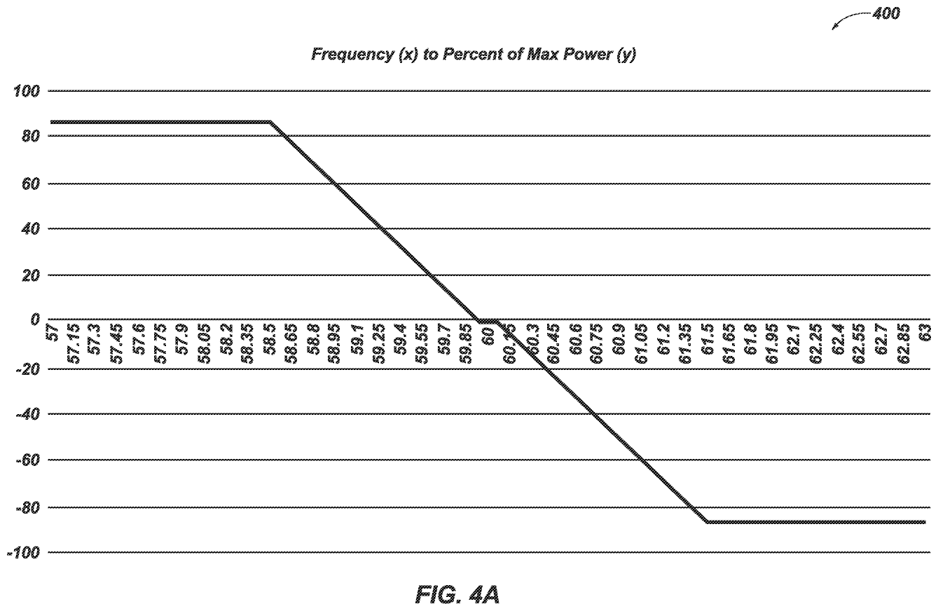

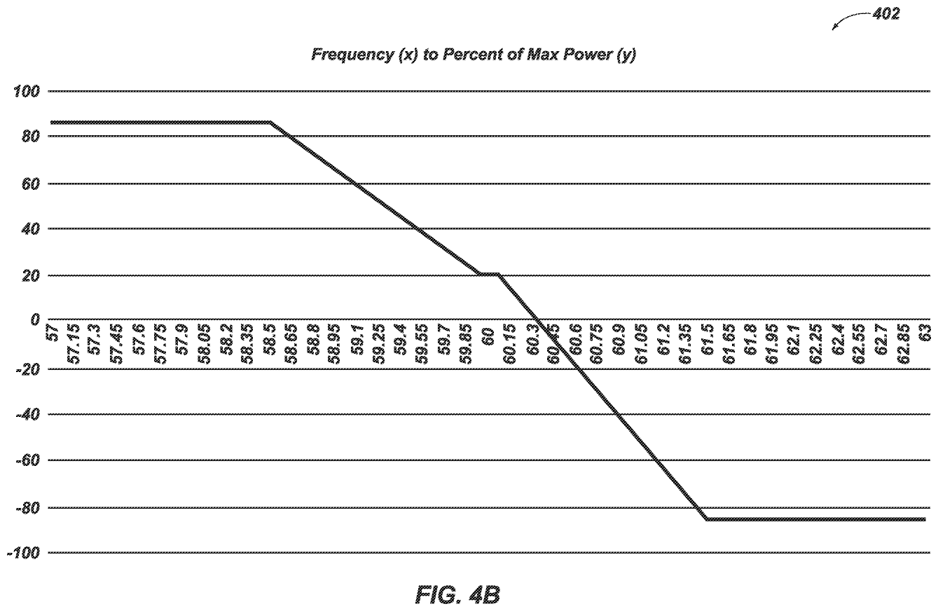

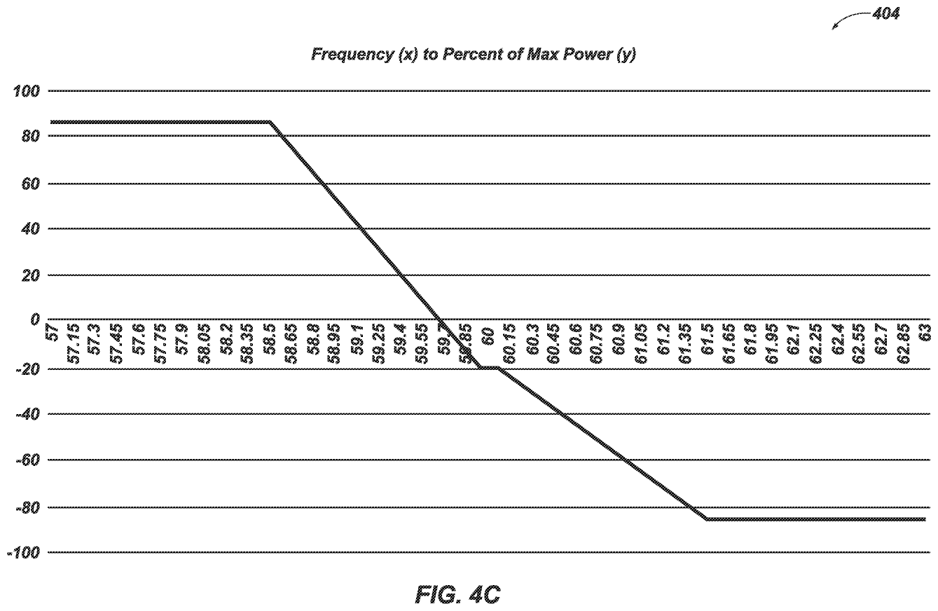

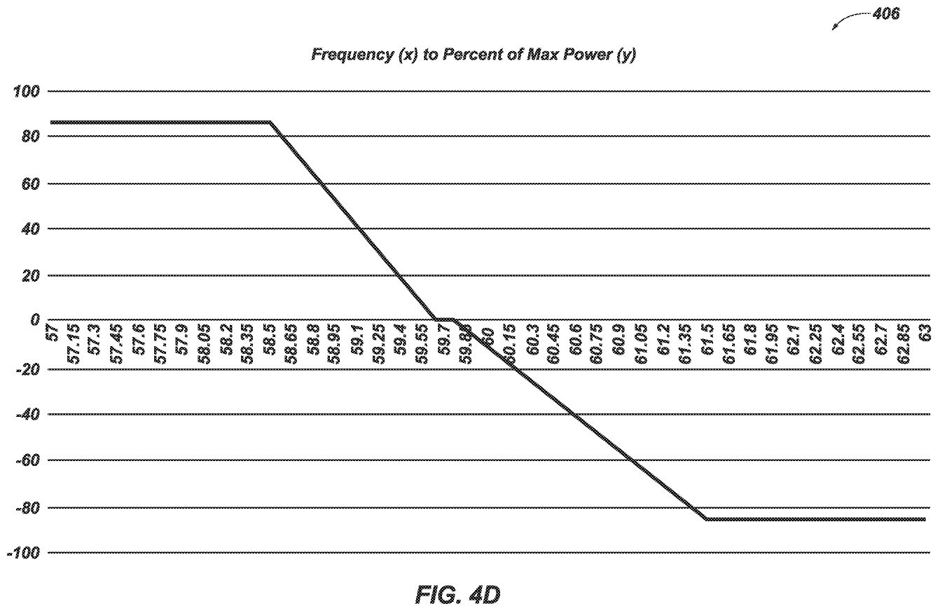

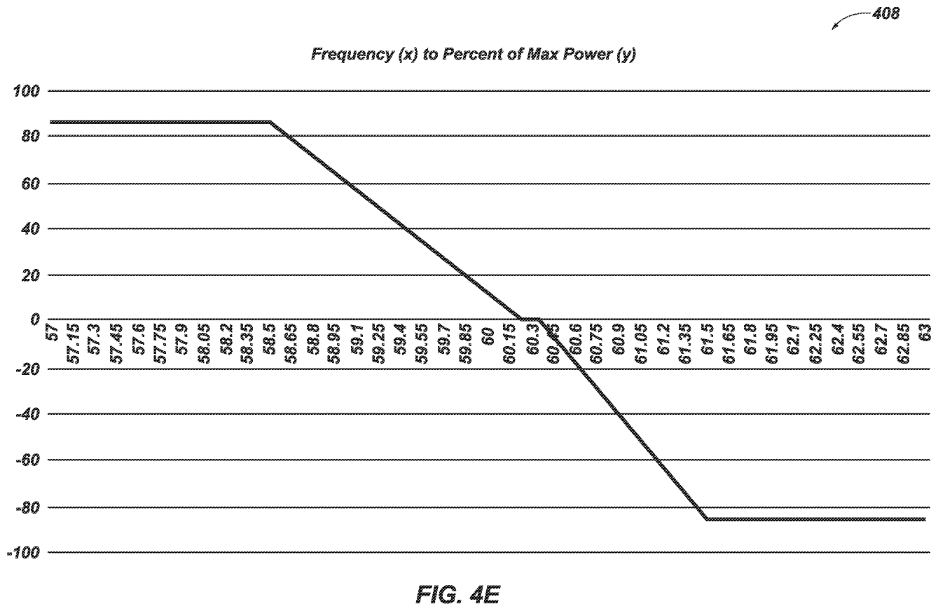

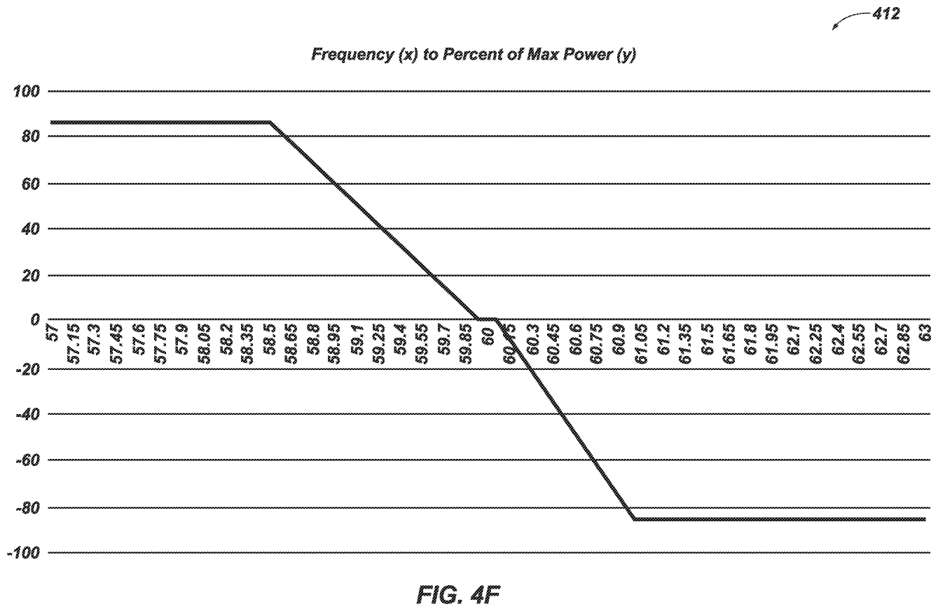

FIGS. 4A-4F illustrate a Frequency-Watt curve illustrating one or more changes made by an operator using the selectable elements of the GUI 300 of FIG. 3A. FIG. 4A illustrates a Frequency-Watt curve 400 centered at 60 Hz. FIG. 4B shows the Frequency-Watt curve 402 which is representative of the Frequency-Watt curve 400 shown in FIG. 4A but modified with a 20% increase (discharging) in a Frequency-Watt bias parameter (e.g., using the Frequency-Watt bias element 312 of GUI 300). FIG. 4C shows the Frequency-Watt curve 404 which is representative of the Frequency-Watt curve 400 shown in FIG. 4A but modified with a 20% decrease (charging) a Frequency-Watt bias parameter (e.g., using the Frequency-Watt bias element 312 of GUI 300). FIG. 4D shows the Frequency-Watt curve 406, which is representative of the Frequency-Watt curve 400 shown in FIG. 4A but modified to have a frequency deadband midpoint of 59.7 Hz (e.g., using the frequency deadband midpoint element 316 of GUI 300). Likewise, FIG. 4E shows the Frequency-Watt curve 408 which is representative of the Frequency-Watt curve 400 shown in FIG. 4A but modified to have a frequency deadband midpoint of 60.3 Hz. FIG. 4F shows the Frequency-Watt curve 410 which is representative of the Frequency-Watt curve 400 shown in FIG. 4A but modified to have a maximum power end point changed from 61.5 Hz to 61.0 Hz (e.g., using the frequency maximum charge element 326 of GUI 300).

Three different example transient response scenarios that may be performed by the microgrid system 100 are listed in Table 1. The transient scenarios demonstrate the functionality of the developed layered inverter Volt-VAR control scheme of the microgrid system 100 to provide voltage support. These transient response scenarios illustrate the control response to regulate the voltage at the interconnection point by absorbing or delivering reactive power. The test scenario results may be scalable to extreme dynamic responses, but the below scenarios represent practical utility grid voltage deviations. The below scenarios demonstrate the instantaneous voltage support that the HP inverter-based Volt-VAR controls of the microgrid system 100 may provide, preventing grid disconnection at the point of interconnection and eliminating the need for significant distribution system upgrades.

TABLE 1
Transient Scenarios
Test Scenario Parameters

| | | Time | Transient | |
|---|---|---|---|---|
| No. | Type | (sec) | Setpoints | kvar |
| 1 | Sag | 0 | T0: 480 V | −6.9 |
| | | 11 | T1: 483 V | 18 |
| | | 78 | T2: 480 V | −6.75 |
| 2 | Swell | 0 | T0: 482 V | −5.13 |
| | | 23 | T1: 480 V | −35.95 |
| | | 50 | T2: 478 V | −67.38 |
| | | 136 | T3: 477 V | −90.2 |
| | | 174 | T4: 480 V | −55.1 |
| 3 | Sag and Swell | 0 | T0: 482 V | −5.25 |
| | | 19 | T1: 481 V | −29.25 |
| | | 47 | T2: 478 V | −52.25 |
| | | 83 | T3: 482 V | −5.25 |

These three transient scenarios display standard and extreme voltage deviations from the grid's 480 V nominal voltage. The first scenario is a standard voltage sag. The second scenario is a step swell transient displaying the relationship between reactive power support and voltage stabilization. The third scenario is an extreme transient event showing a voltage sag and swells while using the power bias to charge one or more energy storage devices 108.

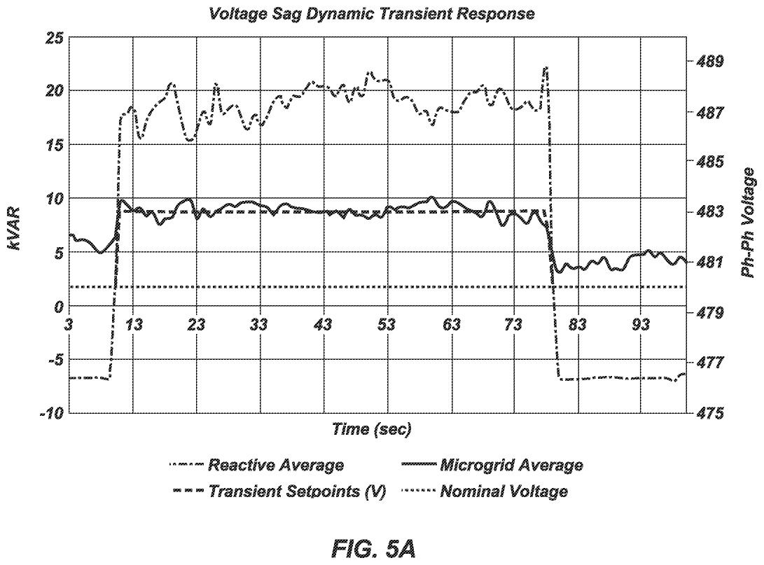

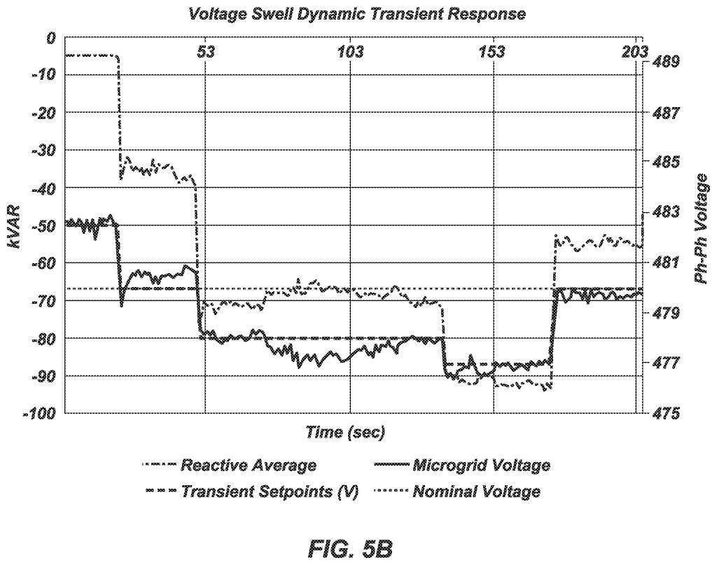

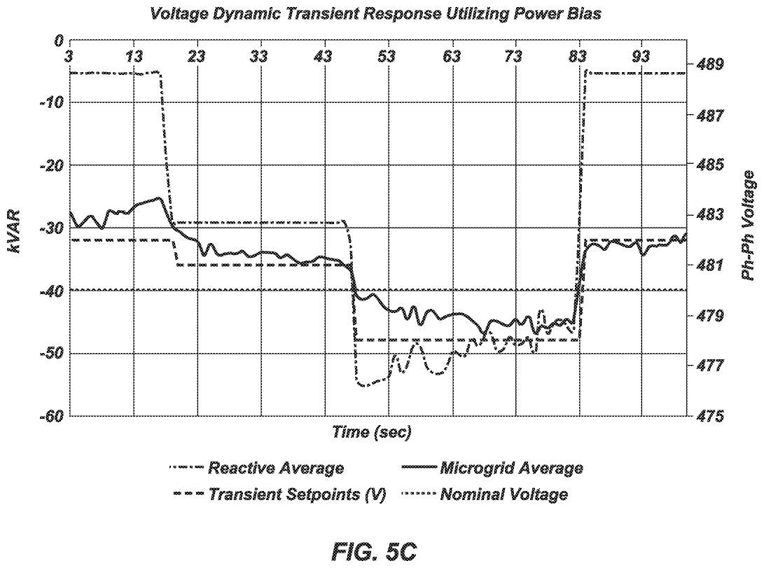

FIGS. 5A-5C respectively show the reaction of the microgrid system 100 responsive to the three scenarios shown in Table 1. For example, FIG. 5A shows an example response of the microgrid system 100 to a voltage sag experienced by the microgrid system 100. A voltage sag typically occurs when a large load is added to an AC bus or other transients (e.g., cloud coverage on PV), demanding an increase in voltage support. Maintaining the grid's voltage at nominal is important to prevent disconnection at the point of common coupling, which may occur if a grid's voltage deviates too far from a set nominal voltage. As the utility's AC grid voltage drops below the nominal voltage, the BESS with the proposed control scheme may provide VAR to maintain grid voltage stability.

Still referring to FIG. 5A, in this scenario, the microgrid system 100 setpoint was switched from 480 V to 483 V to emulate a voltage sag of 3 V at the point of interconnect. Before this sag emulation, the system operated around 481 V, consuming 6.9 kvar. The microgrid immediately responded to the emulated grid's voltage sag by injecting 24 kvar, raising the microgrid's voltage to 483 V in response to the sag. The system was then returned to the nominal center setpoint of 480 V, and the reactive power returned to normal, allowing the microgrid to return to its nominal voltage of 480 V.

In some cases, a microgrid would not require that amount of reactive power to respond to a voltage sag, but the ability of the microgrid system 100 to dynamically respond to a transient while charging the BESS at a rate of 60 kW required more VAR support. In some embodiments, it may take, on average, half as many VAR to control the voltage corresponding to the charge rate of the BESS.

FIG. 5B shows an example response of the microgrid system 100 to a voltage swell experienced by the microgrid system 100. A voltage swell scenario may occur due to a rapid voltage increase on the AC bus that exceeds the deadband limits from nominal voltage. Several transients may cause the grid voltage to surge, including lightning strikes, power grid switching, and electrical component failures. Unlike voltage sags, voltage swells may cause damage to electrical components, including household items.

Before the swell emulation, the microgrid system 100 operated around 482 V center setpoint and consumed 5.13 kvar for 23 seconds. In the first swell starting at 23 seconds, the microgrid system 100 center setpoint was set to 480 V to emulate a voltage swell of 2 V at the point of interconnect. The microgrid system 100 responded to the voltage swell by absorbing 35.95 kvar until the second transient swell starting at 50 seconds. In the second transient swell, the center setpoint was lowered by an additional 2 V to increase the size of the voltage swell. The microgrid system 100 controls responded by absorbing 67.8 kvar until the third transient swell at 136 seconds. The final voltage swell transient reduced the voltage to 477 V with reactive power consumption of 90.2 kvar. The microgrid system 100 was then returned to 480 V at 174 seconds, consuming 55.1 kvar.

FIG. 5C shows an example response of the microgrid system 100 to a voltage sag followed by a voltage swell including a change in voltage bias response. As shown in Table 1, the microgrid system 100 initially operated around 482 V center setpoint and consumed 5.25 kvar for 19 seconds. A power bias of 10% was implemented, causing a voltage decrease while consuming reactive power during this scenario. The first transient implemented at 19 seconds was a voltage swell of 1 V by changing the microgrid testbed's voltage center setpoint from 482 V to 481 V. The microgrid responded by consuming 29.25 kvar from the utility's grid, which stabilized and held until 47 seconds when the next voltage transient was forced, emulating the net voltage swell of 4 V. The microgrid responded by increasing its reactive power consumption from 29.25 kvar to 52.25 kvar. The final voltage transient implemented was a return of the center setpoint voltage back to 482 V, reducing reactive power consumption to 5.25 kvar from the grid. FIG. 5C displays a microgrid testbed reaction to a voltage swell and sag responses utilizing a power bias by consuming and injecting reactive power to the utility to maintain grid stability.

The enhanced Volt-VAR inverter controls respond to extreme transients under a power bias while ensuring grid voltage remains at its nominal voltage. This dynamic control response may independently support transient voltage deviations while enabling charging or discharging. Though discussed in terms of an example showing an inverter changing one or more operating parameters for volt-VAR control, the above scenarios are also applicable to Frequency-Watt inverter controls which may be changed dynamically responsive to changes experienced at a point of connection between an energy source and the microgrid system 100 (e.g., via the inverter 106).

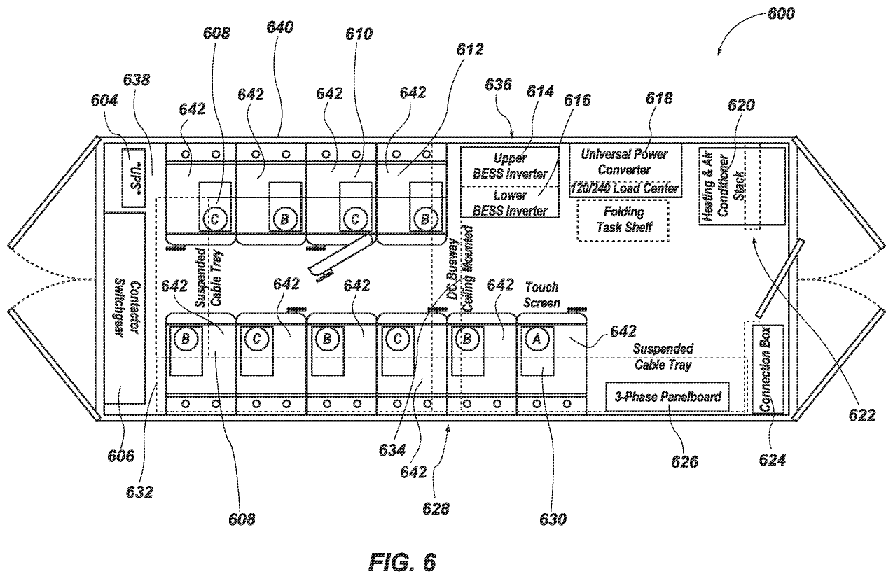

FIG. 6 shows a schematic representation of a top view of an example layout of a portable microgrid system 600 according to one or more embodiments of the disclosure. The portable microgrid system 600 may be one example configuration of the microgrid system 100 discussed above. As shown in FIG. 6, the portable microgrid system 600 may include an uninterruptible power supply (UPS) 604, switchgear 606, passive fire extinguishers 608, an interior wi-fi access point 610, a mini-local area network (LAN) power supply 612, inverter 636, universal power converter 618, heating and air conditioner stack 620, connection box 624, 3-phase panelboard 626, computing device 630, expansion port 628, exhaust shutter 632, an air purge fan and intake shutter 638, a ceiling mounted DC busway 634, and energy storage devices 642. The inverter 636 may include a plurality of different types of inverters. For example, as shown in FIG. 6, inverter 636 includes upper BESS inverter 614 and lower BESS inverter 616. Furthermore, the computing device 630 may include a display (not shown) and one or more I/O device (e.g., a touch screen) (not shown) configured to allow a user to interact with the computing device 630. The various components recited above may reside in a container 640 configured to be mobile (e.g., movable by truck or other transportation methods). In some embodiments, a length of the container 102 may be between about 18 feet to about 22 feet and a height of the container 102 may be from about 8 to about 12 feet.

The connection box 624 may be mounted outside of the container 102. The connection box 624 may allow the deployment or decommissioning of the portable microgrid system 600 by extending some AC wires that connect to breakers of the 3-phase panelboard 626 such that an operator does not have to open any enclosures within the container 102 and may land field wires onto one or more terminal blocks of the connection box 624. The 3-phase panelboard 626 provides overcurrent protective devices (OCPD) and manual disconnect capability for various assets of the portable microgrid system 600. The 3-phase panelboard 626 may include circuit breakers for site loads, inverted PV, an engine generator and for the Wye side of the Delta/Wye isolating transformer. Grid power also may also be connected to the portable microgrid system 600 via the 3-phase panelboard.

The interior wi-fi access point 610 may allow remote systems (e.g., remote user devices or servers) to connect to the portable microgrid system 600. For example, the interior wi-fi access point 610 may allow a remote user device to view or modify one or more operating parameters of the portable microgrid system 600. In some embodiments, the portable microgrid system 600 may also include an exterior wi-fi access point to allow remote systems to connect to the portable microgrid system 600. The heating and air conditioner stack 620 may control an internal temperature of the portable microgrid system 600. The passive fire extinguishers 608 may be configured to activate (e.g., by excreting fire retardant or other substances to suppress fire or heat) responsive to a detected temperature within the portable microgrid system 600 (e.g., within the container housing the system) exceeding a threshold. Moreover, the air purge fan and intake shutter 638 and the exhaust shutter 632 may serve to regulate the flow of air into and out of the container 640. The universal power converter 618 may allow converting electrical power between different voltage levels or frequencies. For example, the universal power converter 618 may be configured to convert electrical currents received from a plurality of different energy sources (e.g., solar panels, wind turbines, or conventional generators) into a uniform format compatible with the portable microgrid system 600. In some embodiments, the exhaust shutter 632 may be in the form of a louver disposed in a side of the container 102. In some embodiments, the exhaust shutter 632 may be activated (e.g., opened) responsive to a detected temperature of the interior of the container being above a pre-determined threshold. Though shown in FIG. 6 as having a particular layout, any layout may be used so long as the container 640 is capable of carrying the various components to allow the portable microgrid system 600 to be mobile.

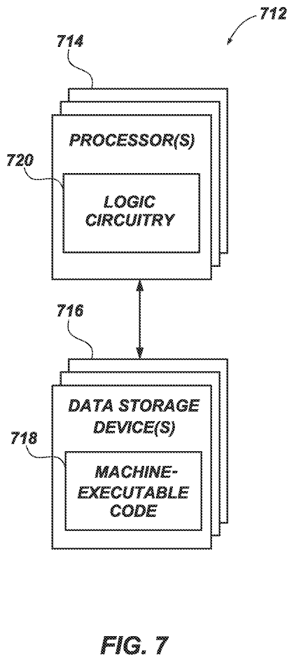

It will be appreciated by those of ordinary skill in the art that functional elements of examples disclosed herein (e.g., functions, operations, acts, processes, and/or methods) may be implemented in any suitable hardware, software, firmware, or combinations thereof. FIG. 7 illustrates non-limiting examples of implementations of functional elements disclosed herein. In some examples, some or all portions of the functional elements disclosed herein may be performed by hardware specially configured for carrying out the functional elements.

FIG. 7 is a block diagram of circuitry 712 that, in some examples, may be used to implement various functions, operations, acts, processes, and/or methods disclosed herein. The circuitry 712 includes one or more processors 714 operably coupled to one or more energy storage devices 108 (also referred to herein as “storage 716”). The storage 716 includes machine executable code 718 stored thereon and the processors 714 include logic circuitry 720. The machine executable code 718 includes information describing functional elements that may be implemented by (e.g., performed by) the logic circuitry 720. The logic circuitry 720 is adapted to implement (e.g., perform) the functional elements described by the machine executable code 718. The circuitry 712, when executing the functional elements described by the machine executable code 718, should be considered as special purpose hardware configured for carrying out functional elements disclosed herein. In some examples the processors 714 may perform the functional elements described by the machine executable code 718 sequentially, concurrently (e.g., on one or more different hardware platforms), or in one or more parallel process streams.

When implemented by logic circuitry 720 of the processors 714, the machine executable code 718 is to adapt the processors 714 to perform operations of examples disclosed herein. For example, the machine executable code 718 may adapt the processors 714 to perform at least a portion or a totality of the process 200 of FIG. 2. As another example, the machine executable code 718 may adapt the processors 714 to perform at least a portion or a totality of the operations discussed for the apparatus of FIG. 2.

The processors 714 may include a general purpose processor, a special purpose processor, a central processing unit (CPU), a microcontroller, a programmable logic controller (PLC), a computer-based controller (e.g., a real time automation controller), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer executes functional elements corresponding to the machine executable code 718 (e.g., software code, firmware code, hardware descriptions) related to examples of the disclosure. It is noted that a general-purpose processor (may also be referred to herein as a host processor or simply a host) may be a microprocessor, but in the alternative, the processors 714 may include any conventional processor, controller, microcontroller, or state machine. The processors 714 may also be implemented as a combination of computing devices, such as a combination of a DSP and a microprocessor, a plurality of microprocessors, one or more microprocessors in conjunction with a DSP core, or any other such configuration.

In some examples the storage 716 includes volatile data storage (e.g., random-access memory (RAM)), non-volatile data storage (e.g., Flash memory, a hard disc drive, a solid state drive, erasable programmable read-only memory (EPROM), etc.). In some examples the processors 714 and the storage 716 may be implemented into a single device (e.g., a semiconductor device product, a system on chip (SOC), etc.). In some examples the processors 714 and the storage 716 may be implemented into separate devices.

In some examples the machine executable code 718 may include computer-readable instructions (e.g., software code, firmware code). By way of non-limiting example, the computer-readable instructions may be stored by the storage 716, accessed directly by the processors 714, and executed by the processors 714 using at least the logic circuitry 720. Also by way of non-limiting example, the computer-readable instructions may be stored on the storage 716, transferred to a memory device (not shown) for execution, and executed by the processors 714 using at least the logic circuitry 720. Accordingly, in some examples the logic circuitry 720 includes electrically configurable logic circuitry 720.

In some examples the machine executable code 718 may describe hardware (e.g., circuitry) to be implemented in the logic circuitry 720 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, VERILOG™, SYSTEMVERILOG™ or very large scale integration (VLSI) hardware description language (VHDL™) may be used.

HDL descriptions may be converted into descriptions at any of numerous other levels of abstraction as desired. As a non-limiting example, a high-level description may be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuitry 720 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples the machine executable code 718 may include an HDL, an RTL, a GL description, a mask level description, other hardware description, or any combination thereof.

In examples where the machine executable code 718 includes a hardware description (at any level of abstraction), a system (not shown, but including the storage 716) may implement the hardware description described by the machine executable code 718. By way of non-limiting example, the processors 714 may include a programmable logic device (e.g., an FPGA, PLC, or computer-based controller) and the logic circuitry 720 may be electrically controlled to implement circuitry corresponding to the hardware description into the logic circuitry 720. Also by way of non-limiting example, the logic circuitry 720 may include hard-wired logic manufactured by a manufacturing system (not shown, but including the storage 716) according to the hardware description of the machine executable code 718.

Regardless of whether the machine executable code 718 includes computer-readable instructions or a hardware description, the logic circuitry 720 is adapted to perform the functional elements described by the machine executable code 718 when implementing the functional elements of the machine executable code 718. It is noted that although a hardware description may not directly describe functional elements, a hardware description indirectly describes functional elements that the hardware elements described by the hardware description are capable of performing.

In the preceding detailed description, reference is made to the accompanying drawings, which form a part hereof, and in which are shown, by way of illustration, specific examples of embodiments in which the disclosure may be practiced. These embodiments are described in sufficient detail to enable a person of ordinary skill in the art to practice the disclosure. However, other embodiments enabled herein may be utilized, and structural, material, and process changes may be made without departing from the scope of the disclosure.

The illustrations presented herein are not meant to be actual views of any particular method, system, device, or structure, but are merely idealized representations that are employed to describe the embodiments of the disclosure. In some instances, similar structures or components in the various drawings may retain the same or similar numbering for the convenience of the reader; however, the similarity in numbering does not necessarily mean that the structures or components are identical in size, composition, configuration, or any other property.

The preceding description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawings may be arranged and designed in a wide variety of different configurations. Thus, the following description of various embodiments is not intended to limit the scope of the disclosure, but is merely representative of various embodiments. While the various aspects of the embodiments may be presented in the drawings, the drawings are not necessarily drawn to scale unless specifically indicated.

Furthermore, specific implementations shown and described are only examples and should not be construed as the only way to implement the disclosure unless specified otherwise herein. Elements, circuits, and functions may be shown in block diagram form in order not to obscure the disclosure in unnecessary detail. Conversely, specific implementations shown and described are exemplary only and should not be construed as the only way to implement the disclosure unless specified otherwise herein. Additionally, block definitions and partitioning of logic between various blocks is exemplary of a specific implementation. It will be readily apparent to one of ordinary skill in the art that the disclosure may be practiced by numerous other partitioning solutions. For the most part, details concerning timing considerations and the like have been omitted where such details are not necessary to obtain a complete understanding of the disclosure and are within the abilities of persons of ordinary skill in the relevant art.

Those of ordinary skill in the art will understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the disclosure may be implemented on any number of data signals including a single data signal.

The various illustrative logical blocks, modules, and circuits described in connection with the embodiments disclosed herein may be implemented or performed with a general purpose processor, a special purpose processor, a digital signal processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is configured to execute computing instructions (e.g., software code) related to embodiments of the disclosure.

The embodiments may be described in terms of a process that is depicted as a flowchart, a flow diagram, a structure diagram, or a block diagram. Although a flowchart may describe operational acts as a sequential process, many of these acts may be performed in another sequence, in parallel, or substantially concurrently. In addition, the order of the acts may be re-arranged. A process may correspond to a method, a thread, a function, a procedure, a subroutine, a subprogram, other structure, or combinations thereof. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may include one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.,” or “one or more of A, B, and C, etc.,” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

While the disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. A microgrid system comprising:
a portable enclosure containing;
at least one energy storage device;
at least one inverter operably connected to the at least one energy storage device;
a switchgear operably connected to the at least one inverter;
at least one processor; and
at least one non-transitory computer readable storage medium storing instructions thereon that, when executed by the at least one processor, cause the microgrid system to:
measure, at a point-of-interconnect of the microgrid system, a frequency and a voltage to generate first frequency data or first voltage data;
provide, via a graphical user interface (GUI) of the microgrid system, the first frequency data or the first voltage data to an operator of the microgrid system;
receive one or more of a center point voltage parameter, a center point frequency parameter, and a power discharge bias parameter; and
while maintaining active operation of the at least one inverter, update one or more operating parameters of the at least one inverter responsive to the received one or more of the center point voltage parameter, the center point frequency parameter, and the power charge/discharge bias parameter.

2. The microgrid system of claim 1, wherein the instructions stored on the at least one non-transitory computer readable storage medium, when executed by the at least one processor, cause the microgrid system to detect, at the point-of-interconnect, when an operating voltage or operating frequency has deviated from a respective pre-defined voltage range or a pre-defined frequency range.

3. The microgrid system of claim 2, wherein the instructions stored on the at least one computer readable storage medium, when executed by the at least one processor, cause the microgrid system to provide, to an operator via the GUI, one or more alerts responsive to detecting the operating voltage or the operating frequency has deviated from the pre-defined voltage range or the pre-defined frequency range.

4. The microgrid system of claim 2, wherein the pre-defined voltage range corresponds to a deadband voltage defined by a Volt-VAR curve and the pre-defined frequency range corresponds to a deadband frequency defined by a Frequency-Watt curve.

5. The microgrid system of claim 1, wherein the at least one energy storage device comprises one or more lithium iron phosphate batteries.

6. The microgrid system of claim 1, wherein the at least one inverter is configured to switch between a 415/230 VAC at 50 Hz, three-phase power rating and a 480/277 VAC at 60 Hz three-phase power rating.

7. The microgrid system of claim 1, wherein the at least one inverter comprises controls configured to control one or more operations of the at least one inverter while on, grid-tied, islanded, generator-tied, or operating.

8. The microgrid system of claim 1, further comprising a louver and a venting system coupled to the louver, wherein the venting system is configured to push air within the portable enclosure out of the portable enclosure via the louver responsive to detecting a temperature within the portable enclosure exceeding a predetermined threshold.

9. The microgrid system of claim 1, wherein a length of the portable enclosure comprises a range from about 18 feet to about 22 feet.

10. The microgrid system of claim 1, wherein a height or width of the portable enclosure comprises a range from about 8 to about 12 feet.

11. A method comprising:
measuring, at a point-of-interconnect of at least one inverter of a microgrid system, a frequency and a voltage to generate first frequency data or first voltage data;
providing, via a graphical user interface (GUI) of the microgrid system, the first frequency data or the first voltage data to an operator of the microgrid system;
receiving one or more of a center point voltage parameter, a center point frequency parameter, and a power discharge bias parameter; and
while maintaining active operation of the at least one inverter, updating one or more operating parameters of the at least one inverter responsive to the received one or more of the center point voltage parameter, the center point frequency parameter, and the power charge/discharge bias parameter.

12. The method of claim 11, further comprising providing or absorbing reactive power to or from a power grid responsive to updating one or more operating parameters of the at least one inverter.

13. The method of claim 11, further comprising updating one or more charge or discharge profiles of one or more energy storage devices responsive to the received power discharge bias parameter.

14. The method of claim 11, further comprising detecting, at the point-of-interconnect, when an operating voltage or operating frequency has deviated from a respective pre-defined voltage range or pre-defined frequency range.

15. The method of claim 14, further comprising providing, to an operator via the GUI, one or more alerts responsive to detecting the operating voltage or the operating frequency has deviated from the pre-defined voltage range or pre-defined frequency range.

16. The method of claim 14, wherein the pre-defined voltage range corresponds to a deadband voltage defined by a Volt-VAR curve and the pre-defined frequency range corresponds to a deadband frequency defined by a Frequency-Watt curve.

17. The method of claim 13, wherein the one or more energy storage devices comprise one or more lithium iron phosphate batteries.

18. A non-transitory computer-readable medium storing instructions thereon that, when executed by at least one processor, cause the at least one processor to perform steps comprising:
measure, at a point-of-interconnect of a microgrid system, a frequency and a voltage to generate first frequency data or first voltage data;
provide, via a graphical user interface (GUI) of the microgrid system, the first frequency data or the first voltage data to an operator of the microgrid system;
receive one or more of a center point voltage parameter, a center point frequency parameter, and a power discharge bias parameter; and
while maintaining active operation of at least one inverter, update one or more operating parameters of the at least one inverter responsive to the received one or more of the center point voltage parameter, the center point frequency parameter, and the power charge/discharge bias parameter.

19. The non-transitory computer-readable medium of claim 18, further storing instructions thereon that, when executed by the at least one processor, cause the at least one processor to provide or absorb reactive power to or from a power grid responsive to updating one or more operating parameters of the at least one inverter.

20. The non-transitory computer-readable medium of claim 18, further storing instructions thereon that, when executed by the at least one processor, cause the at least one processor to update one or more charge or discharge profiles of one or more energy storage devices responsive to the received power discharge bias parameter.
